(19) United States
(12) Patent Application Publication
(10) Pub. No.: US 2003/0183518 A1
(43) Pub. Date: Oct. 2, 2003

(54) Concave sputtering apparatus

(76) Inventors: David A. Glocker, Rush, NY (US); Mark Romach, Spencerport, NY (US)

Correspondence Address: Ronald J. Kisicki, Esq., JAECKLE, FLEISCHMANN & MUGEL, LLP, 39 State Street, 2nd Floor, Rochester, NY, 14614-1310, US

(21) Appl. No.: 10/395,630

(22) Filed: Mar. 24, 2003

Related U.S. Application Data
(60) Provisional application No. 60/368,105, filed on Mar. 27, 2002.

(51) Int. Cl. C23C 14/34

(52) U.S. Cl. 204/298.18; 204/298.09; 204/298.12; 204/298.19

(57) ABSTRACT

A sputtering cathode comprising a concave surface for receiving and supporting a sputtering target having a substantially conformal concave shape. The cathode is cooled via passage of a suitable coolant through passageways within the cathode. The target is constrained to the cathode along the target periphery. The target expands thermally during sputtering, but being constrained laterally the target is forced into intimate contact with the cooled concave cathode surface. The target is thus cooled over its entire surface, resulting in predictable, uniform erosion rates and target wear, whereas prior art planar cathodes are known to suffer from undesirable buckling of the target away from the cathode due to thermal expansion of the target in use. Cathodes and targets in accordance with the invention are non-planar and preferably are either spherically or cylindrically concave.

### RELATIONSHIP TO OTHER APPLICATIONS AND PATENTS

The present application draws priority from a U.S. Provisional Patent Application Serial No. 60/368,105, filed Mar. 27, 2002.

### TECHNICAL FIELD

The present invention relates to apparatus for sputtering; and, more particularly, to a cathode having a concave surface supportive of a convex target surface.

### BACKGROUND OF THE INVENTION

Sputtering cathodes are well known in the vacuum coating industry. They are widely used to deposit a variety of materials on substrates such as electronic components, computer data storage devices, optical elements, cutting tools and so on. A sputtering cathode produces a plasma in a reduced atmosphere of gas and accelerates ions from the plasma toward a solid source of the coating material, or target. These ions strike the target with sufficient energy to liberate atoms, which then condense on the substrate to form the desired coating.

Many shapes have been described for sputtering cathodes including planar, cylindrical, and conical. Each of these shapes has particular advantages for certain applications.

Planar cathodes are the most common type. In planar cathodes, the targets are flat plates that are bolted to or clamped to the cathode body. Cathodes may contain magnets for producing a dense plasma in front of the target (so called magnetron cathodes), elements that provide for water cooling the target, vacuum sealing surfaces to prevent the cooling water from leaking into the vacuum chamber, and electrical connections to a power supply outside of the vacuum chamber. Other components, such as shielding, gas distribution tubes, and the like may also be included.

To achieve appreciable deposition rates in manufacturing processes, high electrical powers are used and the targets must be cooled. This is typically done in one of two ways. The targets can be cooled by direct contact with circulating water (directly cooled) or by being clamped to a plate which itself is cooled through contact with water (indirectly cooled).

The more efficient of these two methods is direct cooling, because water in contact with the target carries the heat away very efficiently. However, directly cooled targets require vacuum seals between the target and cathode body to prevent the cooling water from leaking into the coating chamber. This makes changing the targets troublesome and unreliable because such seals are often a source of vacuum leaks. Furthermore, as the target is consumed in use there is the possibility of breaking into the water channel with disastrous consequences for the equipment. Finally, defects in targets can allow cooling water to leak through them into the vacuum chamber.

Indirectly cooled targets are more widely used because they avoid the problems of direct cooling. However, maintaining efficient cooling at high powers is a problem with indirectly cooled targets. Because there is no appreciable heat transfer through convection or radiation in a vacuum, extremely good mechanical contact between the cooled cathode body and the target is essential. This requires the target to be tightly clamped or bolted to the cathode body. Bolts may also be used along the center portion of the target in some cases. An alternative method that avoids the need for holes in the target is to secure it around the edges with clamps that bolt to the cathode. However, in either case, only the co-planarity of the target and cathode body keeps them in contact in non-bolted regions.

Importantly, as a target expands and changes shape under the heat loads of high rate sputtering, thermal contact between the target and cathode body can be lost. Because the heat load on the target results from the sputtering process, the target side facing the plasma is at a higher temperature than the side adjacent to the cathode. In a planar target, differential expansion due to this temperature gradient causes the target to bow away from the cooling surface, resulting in reduced thermal contact. In addition, because the target expands more than the cathode and is constrained at the edges, the result is an additional tendency of the target to bow away from the cathode. For these reasons, indirectly cooled planar targets are known in the prior art to overheat readily at high sputtering powers. The consequences of overheating can be difficulty in maintaining the plasma; uneven or unpredictable sputtering rates and/or deposition uniformity; and target damage.

Furthermore, in using indirectly cooled targets, the large number of bolts that must be removed makes target changing time-consuming and difficult. Therefore, prior art indirectly cooled planar cathodes suffer from at least two disadvantages: Targets are difficult to effectively cool and they are time consuming to install and remove.

It is a principal object of the present invention to provide an improved sputtering cathode with improved target cooling over a wide range of target temperatures.

It is a further object of the invention to provide an improved sputtering cathode wherein the target is simply and quickly changeable.

It is a still further object of the invention to provide an improved sputtering cathode wherein the target is not subject to thermal separation from the cathode and consequent asymmetric distortion.

### SUMMARY OF THE INVENTION

Briefly described, a sputtering cathode in accordance with the invention comprises a body having a concave surface for receiving and supporting a sputtering target having a substantially conformal concave shape. The cathode is cooled via passage of a suitable coolant through a cathode cooling jacket, preferably a system of passageways formed within the cathode. The target is constrained to the cathode along the target periphery. The target expands thermally during sputtering, but being constrained laterally the target is forced into intimate contact with the concave cathode surface. The target is thus cooled over its entire surface, resulting in predictable, uniform erosion rates and target wear; whereas prior art planar cathodes are known to suffer from undesirable buckling of the target away from the cathode due to thermal expansion of the target in use, causing uneven erosion and possible target damage. Cathodes and targets in accordance with the invention are non-planar and preferably are either spherically or cylindrically concave.

### BRIEF DESCRIPTION OF THE DRAWINGS

The present invention will now be described, by way of example, with reference to the accompanying drawings, in which:

FIG. 1 is a plan view of a prior art planar cathode wherein an array of bolts fastens the target to the cathode body;

FIG. 2 is a cross-section view of taken along line 2-2 in FIG. 1;

FIG. 3 is an end view of a prior art inverted cylindrical cathode, showing the relationship of the target to the cathode body;

FIG. 4 is a cross-sectional view of the cathode shown in FIG. 3;

FIG. 4a is a cross-sectional view of a slotted cylindrical target in accordance with the invention;

FIG. 5 is an elevational view of a first arcuate cathode in accordance with the invention;

FIG. 6 is a cross-sectional view taken along line 6-6 in FIG. 5;

FIG. 7 is an elevational view of a second arcuate cathode in accordance with the invention;

FIG. 8 is an elevational view of a third arcuate cathode in accordance with the invention;

FIG. 9 is a cross-sectional view taken along line 9-9 in FIG. 8; and

FIG. 10 is a diametrical cross-sectional view of a spherical cathode in accordance with the invention.

### DESCRIPTION OF THE PREFERRED EMBODIMENTS

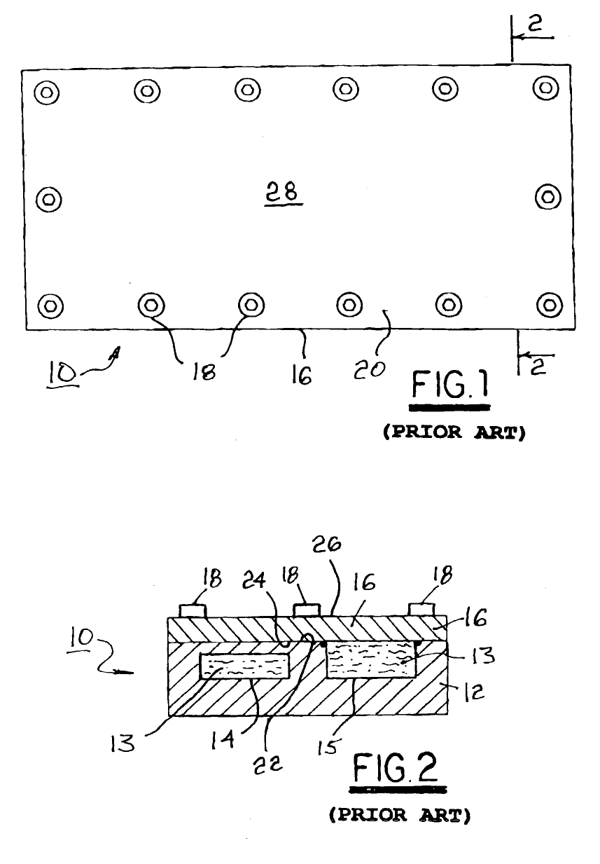

Referring to FIGS. 1 and 2, a prior art planar cathode 10 includes a hollow cathode body 12 having one or more passageways 14 within cathode body 12 defining a cooling jacket for body 12 for circulation of coolant 13, such as water, via a conventional liquid cooling system (not shown). Preferably, the coolant does not come into contact with the target, as in passageway 14, although configurations such as passageway 15 are known in the art and are within the scope of the invention, wherein coolant 13 is in direct contact with target 16. A planar target 16 is mechanically attached to body 12 via a plurality of bolts 18 spaced along the periphery 20 of target 16. The target may also be attached by using bolts that pass through the cathode body into threaded holes in the back of the target (not shown). Cathode body 12 and target 16 make mechanical contact therebetween along mating surfaces 22,24, respectively. Heat from target 16, created during sputtering of target material from upper surface 26, flows through target 16, across mating surfaces 22,24, through body 12, and is absorbed by coolant passing through passageways 14,15. Contact between the mating surfaces in the central region 28 relies on maintaining coplanarity of these surfaces, as the body and target are not physically constrained therein. As is known in the art and described above, process heating causes planar target 16, constrained along its periphery 20, to thermally bow away from body 12, thus losing cooling contact therewith and thereby accelerating deformation.

Still referring to FIG. 1, prior art cathode 10 is shown as being rectangular in area. As is obvious to one of ordinary skill in the art of sputtering, however, the sputtering surface of a planar cathode may assume other shapes, for example, circular or oval (not shown).

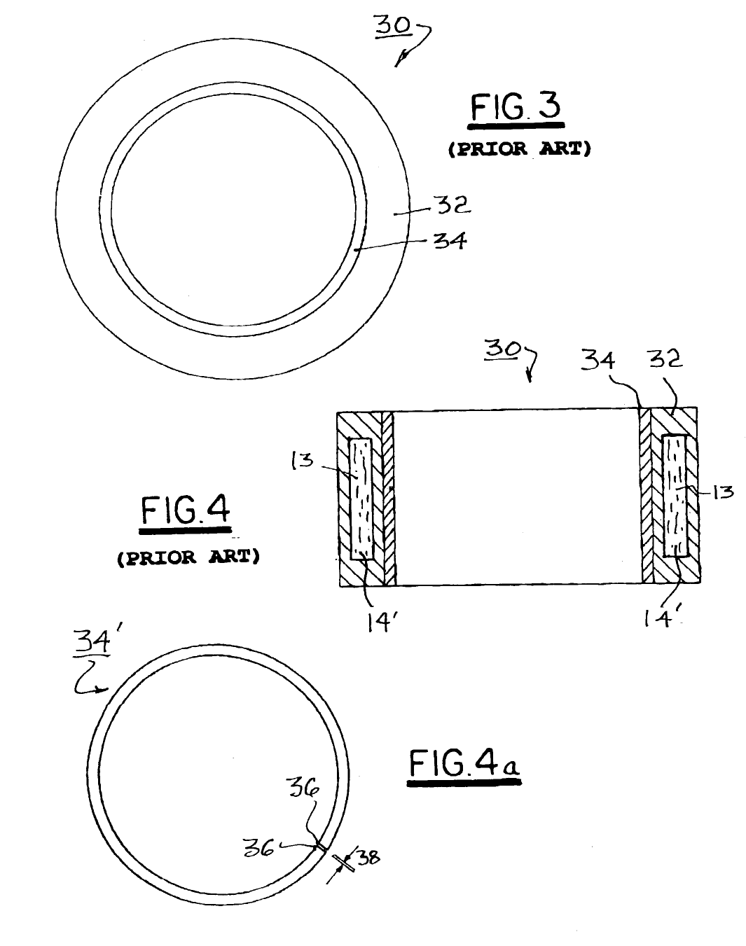

Referring to FIGS. 3 and 4, a particular prior art cathode configuration that overcomes these difficulties is an inverted cylindrical cathode 30. In an inverted cylindrical cathode, the cathode body 32 is a cylinder and the target 34 is a tube that can be inserted into the cylinder, as shown in FIGS. 3 and 4. As the target heats up under use, it expands in surface area, just as in the case of a planar magnetron target. However, in an inverted cylindrical cathode, such known expansion increases the cylinder diameter, thus causing the target to be pressed into ever more forceful contact with the cathode, which is cooled by coolant 13 passed through passageway 14′. In this way, the target reaches an equilibrium temperature, uniform around the circumference of the target surface, and the problems of indirect cooling experienced in planar cathodes can be avoided. A further obvious advantage of an inverted cylindrical cathode is that the target needs no bolting or clamping to hold it in place. A cool target can simply slide into or out of a cooled cathode body and then be retained therein by thermal expansion of the target material.

Referring FIG. 4a, we have found further that a target 34′ in accordance with the invention, for an inverted cylindrical cathode, need not be a continuous cylinder. A sheet of target metal whose length approximates the inside circumference of the cylindrical cathode body 32 (FIGS. 3 and 4) may be rolled into the form of a slotted cylinder and inserted into the cathode body. Surprisingly, under the forces produced by target heating, the sheet ends 36 abutting at the slot 38 do not overlap but rather form a tight seam that performs during sputtering as if the target were a continuous tube. Rolled targets with thicknesses as low as 0.010 inches have been inserted and successfully sputtered. Such rolled targets may be formed from a wide variety of sheet materials, ranging in mechanical properties from gold, which is extremely soft, to refractory metals such as titanium, tantalum and molybdenum, which are relatively hard.

Referring to FIGS. 5 through 9, the present invention uses this surprising result in the design of a new indirectly cooled sputtering cathode. One advantage of this new design is the speed and ease with which targets can be installed or removed. Another advantage is that excellent thermal contact is maintained between the target and cooled cathode body, even under very high heat loads to the target. A third advantage is the very low cost of target fabrication. A fourth advantage is the ease and ability to inexpensively make targets of different materials.

Cathodes in accordance with the invention comprise a concave cooled body into which a similarly curved target is placed. The target is fixed only at the ends and thermal expansion during use forces the target into increasingly intimate contact with the cathode body. In this way the ease of target installation and efficient cooling of inverted cylindrical cathodes are possible in a more open geometry.

FIGS. 5 and 6 illustrate cathode 50 in accordance with the invention. Curved target 54, convex on first surface 55 and concave on second surface 57 opposite surface 55, preferably is optionally secured to concave surface 59 of curved cathode body 52 at the ends 56 of the cathode by conventional clamps or bolts (not shown). A step or ridge 58 along the arc of the cathode may also be used simply to position target 54 on the cathode in the transverse direction, as shown in FIG. 6. The cathode is cooled conventionally via coolant passageway 14″. To further improve thermal contact, a layer of soft material 60 having a high heat-transfer coefficient, such as indium foil, may be installed between the target and cathode body.

The numerical curvature of the cathode, herein defined as the arc length of the cathode face divided by the radius of curvature of the arc (equal to the angle in radians that the cathode face subtends), can be very small and the cathode will still be effective. For example, a cathode face with a radius of curvature of 10 meters and an arc length of 1 meter will have a curvature of 0.1. In spite of this relatively shallow concavity, the thermal expansion of a target as it heats up leads to improved contact of the target against the cooled cathode body, rather than to poorer target cooling due to warping, as in prior art planar cathodes. Furthermore, the target may be a simple piece of metal of the proper length, formed to the same curvature as the cathode body, and clamped in a simple fashion at either end.

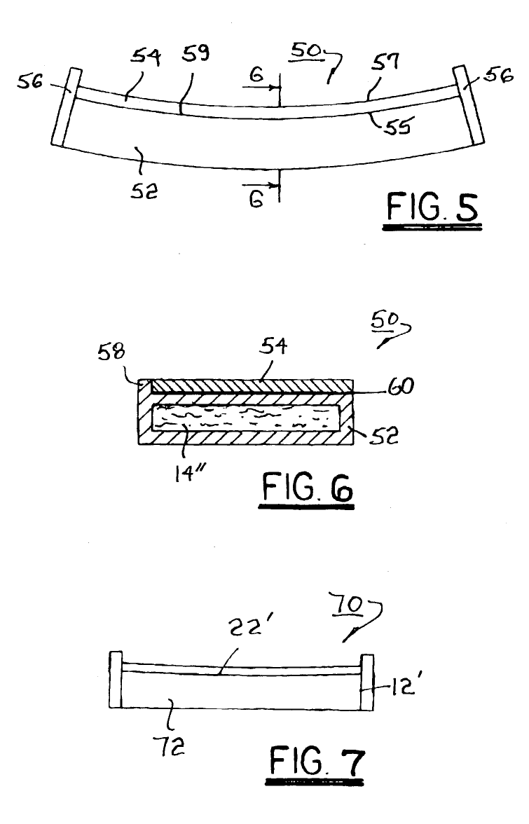

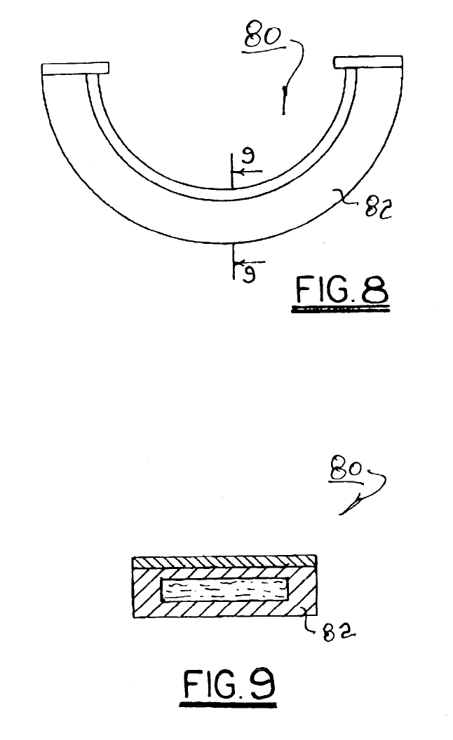

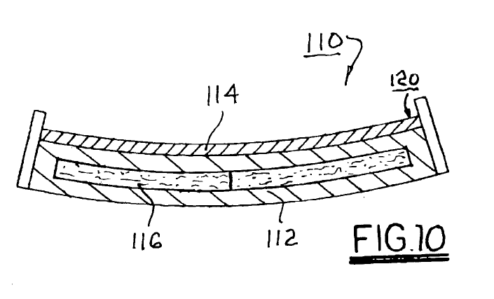

In FIG. 5, the entire body 52 is curved to match the curvature of the target. However, in the case of bodies with relatively small numerical curvature, for ease of manufacture it may be desirable to make only the face of the body curved. For example, FIG. 7 shows a cathode body 72 having a curvature of 0.1 in which the curved cathode surface 22′ has been fashioned in an otherwise rectangular body section 12′. At the opposite extreme, creating a cylindrical cathode body that then is machined into segments can efficiently make cathodes with high curvature. For example, referring to FIGS. 8 and 9, a cathode 80 having a substantially semi-cylindrical body 82 with a numerical curvature of approximately 3 can be made readily by forming a cylindrical cathode such as 30 (FIG. 3), and then cutting it approximately in half.

Unlike prior art planar cathodes, in non-planar cathodes in accordance with the invention, it is not necessary that the target be in intimate contact with the cathode surface at ambient temperature. Even if a small gap exists therebetween, thermal expansion of the target in use will assure excellent thermal contact.

Example: Assume a cathode having a numerical curvature of 0.1 and an arc length of 1.0000 meter. A target fixed at the ends of the cathode with a gap at the target center of 1.0 mm between the rear of the target and the cathode surface must expand only 0.01% to force the target into intimate contact with the cathode. For aluminum, having a thermal expansion coefficient of 0.0024% per degree Celsius, a rise in target temperature of only 4 degrees Celsius is sufficient to assure such contact.

This example shows that the usefulness of the present invention does not rely on extremely close tolerances between the target and cathode surfaces when the parts are fabricated. To the contrary, effective cooling is possible during operation, even with a relatively approximate fit between the target and cathode when assembled and prior to use. A 1 mm gap between the target and cathode would be unacceptable in a prior art planar cathode but can be completely satisfactory in a non-planar cathode in accordance with the invention.

In all of the arcuate cathodes described above, they may incorporate magnets that create a closed so-called “racetrack” sputtering pattern over the curved target face, as is also common in the case of planar magnetron cathodes. The racetrack can be any shape, such as a circle, ellipse, oval, etc. The shape of the desired racetrack can determine the shape of the cathode.

Another configuration, consistent with a circular racetrack, is a domed or convex target 114, also referred to herein as a concave target, fitted into a spherically concave cathode body 112 having a coolant passageway 116. Referring to FIG. 10, the shown cross-sectional view is a diametric cross-section of such a circular, non-planar magnetron 110 and represents all such identical views taken at an infinite number of angular orientations of the diameter. In such a magnetron, target 114 may be clamped to cathode body 112 around their joint perimeter 120.

In non-planar magnetron cathodes in accordance with the invention, the north and south pole strengths of the magnets can be balanced, as is well known in the art, in which configuration substantially all magnetic lines of flux close through the target surface; or they can be unbalanced, in which case some lines of flux close through the target surface and the remaining lines extend away from the target surface. Unbalanced designs are well known in the art for creating a more dense plasma in the coating environment.

The targets used in cathodes in accordance with the invention can be curved pieces of metal of the proper size. Targets may also be formed of material to be sputtered which is bonded to curved pieces of metal by methods such as plasma spraying, hot isostatic pressing, or other methods known in the art. Therefore, there is no restriction as to the type of material that can be sputtered using these cathodes. Further, in keeping with our surprising discovery with respect to cylindrical cathodes, targets in accordance with the invention can be formed from relatively thin sheets of material, in some applications as thin as 0.010 inches in thickness. In prior art indirectly cooled planar targets, such thin material would have to be bonded to a thicker, structural backing plate. The bonding typically is done with solder, pastes or conductive epoxies. All of these methods and materials introduce the possibility of voids in the bond, which can be a source of virtual vacuum leaks and poor thermal contact. Also, the bonding agent can become a contaminant if the sputtering plasma interacts with it. Further, such bonding materials can be insulative and thereby undesirably reduce the cooling efficiency of the cathode jacketing system. The present invention avoids these complications, as well as the additional cost of fabricating backing plates and of reworking backing plates before mounting the next target.

Another advantage conferred by the invention is the ready ability to form composite targets of different materials by laying several curved strips of material in parallel along the face of the cathode and clamping them at their ends. This permits an inexpensive and rapid means of studying the effects of a wide range of compositional alloys for materials such as titanium-aluminum, nickel-titanium, and others, which can exhibit important property changes within a narrow compositional range.

A concave cathode having a relatively small numerical curvature target in accordance with the invention, such as cathode 70 in FIG. 7, offers the advantages cited above but closely approximates the distribution of sputtered material that would be produced by a planar cathode of comparable dimensions. (A planar cathode has an infinite radius and a numerical curvature of zero.) Therefore, such non-planar cathodes can be useful replacements in applications currently employing prior art planar cathodes, such as for coating electronic devices, optics, computer memory devices, and the like.

Concave cathodes having relatively large curvatures, such as cathode 80 shown in FIG. 8, are useful for sputter coating of three dimensional shapes, such as cutting tools, machinery parts, optical fibers, and so on. Additionally, a cathode magnetron having a large curvature, when employed in an unbalanced magnet configuration, results in a very dense plasma in front of the cathode because of the convergence of the unbalanced field. Such convergence cannot occur in unbalanced planar magnetrons, but is described in U.S. Pat. No. 6,497,803, which relates to cylindrical magnetron plasma sources and which is hereby incorporated by reference.

It will be obvious to one skilled in the art that it is possible to combine more than one concave cathode so that the combination works cooperatively. For example, two cathodes which are approximately semi-cylindrical (curvature of approximately 3) can be placed facing one another so that together they surround the parts being coated. This arrangement provides the advantage of complete coverage of complex shapes offered by cylindrical cathodes, but allows the semi-cylindrical cathodes to be spaced apart for ease of substrate loading and target changes. Furthermore, operating two such magnetron cathodes in an unbalanced mode can provide a very dense plasma environment therebetween, as described in the above-incorporated reference.

While the invention has been described by reference to various specific embodiments, it should be understood that numerous changes may be made within the spirit and scope of the inventive concepts described. Accordingly, it is intended that the invention not be limited to the described embodiments, but will have full scope defined by the language of the following claims.

What is claimed is:

1. Apparatus for sputter deposition, comprising:
a) a cathode body having a concave surface and having means for cooling said surface;
b) a target having a convex first surface for mating with said concave cathode surface; and
c) means for constraining said target from lateral expansion along said cathode surface.

2. Apparatus in accordance with claim 1 wherein said target includes a concave second surface for sputter erosion opposite said convex first surface.

3. Apparatus in accordance with claim 1 wherein said means for cooling includes passageways within said cathode body for circulation of a coolant.

4. Apparatus in accordance with claim 3 wherein said passageways are formed such that said coolant does not come into contact with said target.

5. Apparatus in accordance with claim 3 wherein said passageways are formed such that said coolant comes into contact with said target.

6. Apparatus in accordance with claim 1 wherein said target is disposed and restrained with respect to said cathode body such that said target is urged against said cathode surface as said target undergoes thermal expansion with elevated temperature.

7. Apparatus in accordance with claim 1 wherein said target is a portion of a cylinder.

8. Apparatus in accordance with claim 7 wherein said portion of a cylinder subtends about 180°.

9. Apparatus in accordance with claim 1 wherein said target is a portion of a sphere.

10. Apparatus in accordance with claim 1 further comprising a layer of material disposed between said cathode surface and said convex target surface.

11. Apparatus in accordance with claim 1 further comprising at least one magnet disposed adjacent said cathode, said magnet forming a magnetic field containing a plurality of lines of magnetic flux.

12. Apparatus in accordance with claim 11 comprising an array of magnets for creating a confined plasma over said concave target surface.

13. Apparatus in accordance with claim 11 wherein a first portion of said plurality of flux lines closes through said concave target surface and a second portion extends away from said target surface without closing therein.

14. Apparatus in accordance with claim 1 wherein said target is formed of a single material.

15. Apparatus in accordance with claim 1 wherein said target is formed of a plurality of materials.

16. Apparatus in accordance with claim 1 wherein said target is formed of individual strips of different materials.

17. A cathode body for use in sputtering, said cathode body having a concave surface for receiving a target and having means for cooling said surface, said concave surface being selected from the group consisting of a portion of a cylinder and a portion of a sphere.

18. A cathode body in accordance with claim 17 wherein the numerical curvature of said concave surface is between about 0.1 and about 3.0.

19. A cathode body in accordance with claim 17 further comprising a ridge along one edge thereof for positioning said target on said cathode surface.

20. A cathode body in accordance with claim 17 further comprising means for constraining said target onto said concave surface.

21. A cathode body in accordance with claim 17 wherein said surface is concave in two orthogonal dimensions.
